(19) United States
(12) Patent Application Publication
(10) Pub. No.: US 2006/0094259 A1
(43) Pub. Date: May 4, 2006

(54) Forming gas anneal process for high dielectric constant gate dielectrics in a semiconductor fabrication process

(75) Inventors: David C. Gilmer, Austin, TX (US); Olubunmi O. Adetutu, Austin, TX (US); Hsing H. Tseng, Austin, TX (US)

Correspondence Address: FREESCALE SEMICONDUCTOR, INC., MDTX32/PLO2, 770 W PARMER LANE, AUSTIN, TX, 78729, US

(73) Assignee: Freescale Semiconductor, Inc.

(21) Appl. No.: 10/980,445

(22) Filed: Nov. 3, 2004

(51) Int. Cl. H01L 21/4763; H01L 21/31; H01L 21/469

(52) U.S. Cl. 438/785

(57) ABSTRACT

A semiconductor fabrication annealing process includes depositing a high dielectric constant gate dielectric over a substrate and annealing the gate dielectric. Annealing the gate dielectric includes exposing the gate dielectric to an inert ambient and ramping the inert ambient to an annealing temperature. A passivating gas is then introduced into the ambient while maintaining the ambient at the annealing temperature. This passivating ambient is then maintained at the annealing temperature for a specified duration. While maintaining the presence of the passivating gas in the ambient, the ambient temperature is then ramped down from the annealing temperature to a second temperature, which is preferably less than 100° C. The passivating gas is preferably hydrogen gas, deuterium gas, or a combination of the two. The annealing temperature is preferably greater than approximately 470° C.

### FIELD OF THE INVENTION

The present invention is in the field of semiconductor fabrication processes and, more particularly, fabrication processes that use high dielectric constant gate dielectrics.

### RELATED ART

In complementary metal oxide semiconductor (CMOS) fabrication processes, transistors are typically formed by depositing (or growing) a gate dielectric over a wafer substrate, forming a gate electrode over the gate dielectric, and implanting source/drain regions into the substrate using the gate electrode as an implant mask. Thermally formed silicon dioxide gate dielectrics were the most prevalent type of gate electrode for many years. With increased scaling of transistors, however, manufacturers have turned to materials with higher dielectric constants than silicon dioxide for use as gate dielectrics. Higher dielectric constant materials enable manufacturers to form thicker gate dielectrics without sacrificing equivalent oxide thickness (EOT) where the EOT is the dielectric film's actual physical thickness divided by the ratio of the film's dielectric constant to the dielectric constant of silicon dioxide. Other parameters being equal, thicker films are generally more reliable and manufacturable than thinner films.

Unfortunately, high dielectric constant materials tend to exhibit high levels of fixed charges and interface states. Fixed charges and interface states can have undesirable effects on device characteristics (e.g., threshold voltage and drive current) and reliability (e.g., breakdown voltage). Therefore, it is desirable to implement a fabrication process employing high dielectric constant materials that produces a gate dielectric film substantially free of interface states and fixed charges without substantially increasing the cost or complexity of the process.

### BRIEF DESCRIPTION OF THE DRAWINGS

The present invention is illustrated by way of example and not limited by the accompanying figures, in which like references indicate similar elements, and in which:

FIG. 1 is a partial cross sectional view of a semiconductor wafer at an intermediate stage in the formation of an integrated circuit according to one embodiment of the present invention in which isolation dielectrics have been formed in the wafer substrate;

FIG. 2 illustrates processing subsequent to FIG. 1 in which a gate dielectric is formed overlying the wafer substrate;

FIG. 3 illustrates processing subsequent to FIG. 3 in which the gate dielectric is annealed in a forming gas according to the present invention to form a passivated gate dielectric;

FIG. 4 depicts parameters of the anneal process of FIG. 3 according to an embodiment of the invention; and

FIG. 5 illustrates processing subsequent to FIG. 3 in which a transistor is formed on the wafer substrate.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Generally speaking, the present invention is a fabrication process for producing a gate dielectric film using high dielectric constant materials. The process includes a passivation anneal that reduces or eliminates dangling bonds at the surface of the gate dielectric. The anneal is preferably performed in a heated ambient containing a passivating gas such as hydrogen or deuterium. The temperature and gas flow are controlled to optimize the passivation of dangling bonds at or near the dielectric-to-substrate interface. Specifically, depassivation of fulfilled bonds that can occur in conventional anneal processing is reduced by maintaining the presence of the passivating gas while the ambient temperature is ramped down from the annealing temperature. This “post anneal” depassivation prevention enables a higher temperature anneal without incurring substantial depassivation.

Turning now to the drawings, FIG. 1 is a partial cross sectional view of a wafer 101 at selected stage in a semiconductor fabrication process according to one embodiment of the present invention. In the depicted embodiment, wafer 101 includes a silicon-on-insulator (SOI) substrate 102. SOI substrate 102 includes a bulk silicon region 104 overlying a buried oxide (BOX) layer 106. BOX layer 106 is preferably comprised of a film of silicon dioxide. An active or top silicon layer 108 is located overlying BOX 106. Top layer 108 is preferably a single crystal silicon material formed from an epitaxial process. Shallow trench isolation dielectric structures 112 are located on either side of active layer 108. Shallow trench isolation structures 112 are preferably an electrically insulating silicon-oxygen compound such as chemically vapor deposited silicon-oxide. In alternative embodiments (not shown), isolation structures could be implemented with other dielectric materials or with traditional local oxidation of silicon (LOCOS) structures.

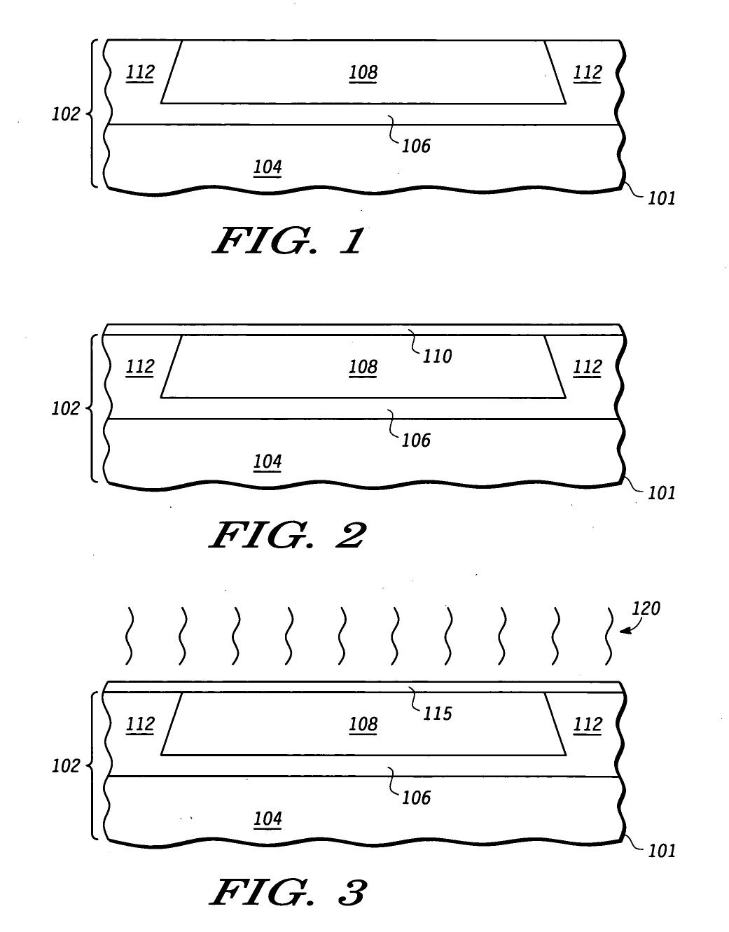

Referring now to FIG. 2, a gate dielectric film 110 is deposited overlying substrate 102. In the preferred embodiment, gate dielectric 110 is a high dielectric constant material. For purposes of this disclosure, a high dielectric constant material is a material having a dielectric constant greater than the dielectric constant of silicon dioxide, which is approximately 3.9. In one embodiment, the high dielectric constant gate dielectric film 110 is an electrically insulating metal oxide that includes a metal element and an oxygen element. Suitable metal oxides include, as an example, HfO₂. In other embodiments, the high dielectric constant material is a metal silicate that includes a metal element and silicon or a metal aluminate that includes a transition metal element, aluminum, and oxygen, Still other embodiments of high dielectric constant film 110 are composed of a metal element, oxygen, and an element such as nitrogen, hafnium, or zirconium. In the preferred embodiment, the equivalent oxide thickness (EOT) of gate dielectric film 110 is less than approximately 2 nm, where a film's EOT equals the film's actual thickness divided by the ratio of the film's dielectric constant to the dielectric constant of silicon dioxide.

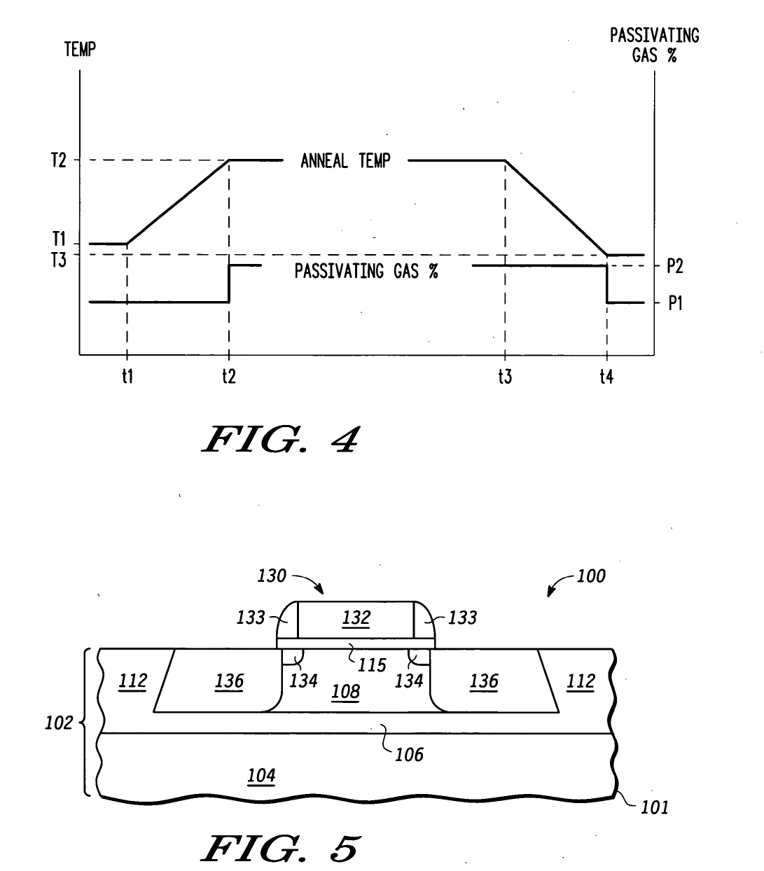

Referring now to FIG. 3, the gate dielectric film 110 of FIG. 2 is passivated with an anneal process identified by reference numeral 120 to form a passivated high dielectric constant gate dielectric 115. The anneal process forms passivated gate dielectric 115, at least in part, by satisfying unfilled or dangling bonds at the interface between gate dielectric 110 and an upper surface of substrate 102. Anneal process 120 may be carried out using a diffusion furnace, a reactor chamber, or other suitable equipment.

In the preferred embodiment, anneal process 120 includes an anneal phase during which dangling bonds are satisfied by exposing the wafer to a passivating ambient or forming gas maintained at a relatively high temperature. The forming gas includes a passivating gas and an inert element. Anneal process 120, according to the preferred embodiment, further includes a temperature ramp down phase during which the presence of the passivating gas is maintained while the ambient temperature is ramped down from the annealing temperature to a relatively low temperature. Maintaining the presence of the passivating gas during the temperature ramp down phase is believed to reduce “depassivation” in which a bond between a passivating gas and a silicon atom disassociates leaving behind and unsatisfied bond.

Referring to FIG. 4, one embodiment of the anneal process 120 is conceptually represented by a plot of the temperature and gas composition of an ambient to which the wafer and gate dielectric are subjected during anneal process 120. The ambient gas composition is indicated in FIG. 4 by the percentage of passivating gas in the ambient. The ambient is preferably a mixture of an inert element or compound and the passivating gas. Accordingly, where FIG. 4 indicates the percentage of passivating gas in the ambient as P2, the percentage of the inert element or compound in the forming gas is (1-P2). The inert element is preferably nitrogen. In the preferred embodiment, the passivating gas is hydrogen gas, deuterium gas, or a combination of both. Hydrogen gas and deuterium gas are efficient in passivating defects at the substrate-dielectric interface.

As depicted in FIG. 4, anneal 120 includes a temperature ramp up portion from time t1 to t2, an anneal portion from time t2 to t3, and a temperature ramp down portion from time t3 to t4. During the temperature ramp up portion of the depicted embodiment, the percentage of the passivating gas is maintained at a first value P1 while the temperature is increased from a first value (T1) to a second value (T2). Although FIG. 4 depicts the temperature ramp as being linear, the actual temperature ramp may be non-linear as well. In the preferred embodiment, P1 is 0 and the inert element is nitrogen such that the ambient is pure nitrogen during the temperature ramp up phase. When the temperature ramp up is completed a time t2, the passivating gas is introduced into the ambient to achieve a passivating ambient or forming gas having a passivating gas percentage of P2.

During the anneal portion from time t2 to t3, the ambient temperature is maintained at the annealing temperature T2 and the percentage of passivating gas in the ambient maintained at P2. During the temperature ramp down phase from time t3 to t4 as depicted in FIG. 4, the passivating gas percentage is maintained at P2 while the temperature is decreased from T2 to T3.

Although FIG. 4 indicates the passivating gas percentage as being constant during the anneal phase and the temperature ramp down phase, alternative implementations may use a third percentage of passivating gas (P3) (not shown) during the temperature ramp down phase from t3 to t4 (where P3 is non-zero). In either implementation, an important benefit is achieved by maintaining the presence of the passivating gas during the temperature ramp down phase. In conventional hydrogen anneal processing, the hydrogen gas is typically purged following the high temperature portion of the anneal and the temperature ramp down proceeds in an entirely inert ambient. In the present invention, the presence of the passivating gas during the temperature ramp down phase is able to reduce the rate of depassivation that occurs.

In one embodiment, the anneal temperature T2 depicted in FIG. 4 is greater than approximately 470° C. This temperature is higher than the temperatures typically recommended for conventional hydrogen anneal processing of SiO₂/Si interfaces, but is believed to result in a more fully passivated interface in the case of high dielectric constant gate dielectrics. In one embodiment, the passivating gas percentage P2 is in the range of approximately 2 to 10%. In an embodiment that uses a third value (P3) for the passivating gas percentage present during the temperature ramp down phase, P3 is also preferably in the range of approximately 2 to 10%. The duration of the anneal portion from time t2 to t3 is preferably in the range of approximately 10 to 50 minutes. The ambient pressure during the anneal process is preferably approximately 100 kPa (one atmosphere). The temperatures T1 and T3 are preferably less than 100° C. (e.g., room temperature or 25° C.).

Referring now to FIG. 5, additional processing of wafer 101 has resulted in the formation of an integrated circuit 100 that includes a transistor 130 where transistor 130 is one of many such transistors formed on wafer 101. Transistor 130 includes a gate electrode 132 formed overlying gate dielectric 115. Extension implants 134 have been formed in top silicon layer 108 self aligned to and disposed on either side of gate electrode 132. Dielectric spacer structures 133 are located on sidewalls of gate electrode 132 and source/drain regions 136 have been formed in top silicon layer 108 self aligned to spacer structures 133 all as will be well known to those in the field of semiconductor fabrication. In the illustrated embodiment, anneal processing 120 of gate dielectric 110 occurs prior to the formation of the gate electrodes and/or source/drain features. In other embodiments, the anneal processing represented by FIG. 4 is performed at the end of wafer processing, subsequent to the formation of the transistors.

In the foregoing specification, the invention has been described with reference to specific embodiments. However, one of ordinary skill in the art appreciates that various modifications and changes can be made without departing from the scope of the present invention as set forth in the claims below. For example, although the transistor 130 depicted is a single gate transistor typical of a volatile memory or logic device, the transistor may be a nonvolatile memory (NVM) device, such as a floating gate structure. Similarly, although the depicted transistor 130 includes extension implants 134, the transistor may include other implant elements such as halo implements, adjust implants, and so forth. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication process, comprising:
depositing a gate dielectric overlying a semiconductor substrate, wherein the gate dielectric comprises a high dielectric constant material;
annealing the gate dielectric, wherein said annealing comprises:
exposing the gate dielectric to an inert ambient and ramping the inert ambient to an annealing temperature;
introducing a passivating gas into the ambient while maintaining the ambient at the annealing temperature to expose the gate dielectric to a passivating ambient;
maintaining the passivating ambient at the annealing temperature for a first duration; and
maintaining the presence of the passivating gas in the ambient while ramping the ambient temperature down from the annealing temperature to a second temperature.

2. The method of claim 1, wherein depositing the gate dielectric comprises depositing a high dielectric constant gate dielectric over the semiconductor substrate.

3. The method of claim 1, wherein depositing the gate dielectric comprises depositing a gate dielectric material having a composition of metal and an element selected from the group consisting of oxygen, nitrogen, hafnium, zirconium, aluminum, and silicon.

4. The method of claim 1, wherein the introducing the passivating gas comprises introducing a gas selected from the group consisting of hydrogen gas and deuterium gas into the ambient.

5. The method of claim 4 wherein the passivating gas includes an inert element.

6. The method of claim 4, wherein the annealing temperature is greater than approximately 470° C.

7. The method of claim 6, wherein the second temperature is less than approximately 100° C.

8. The method of claim 7, wherein a pressure of the passivating ambient is approximately 100 kPa.

9. The method of claim 8, wherein the first duration is in the range of approximately 10 to 50 minutes.

10. A method of forming a gate dielectric in a semiconductor fabrication process, comprising:
depositing a high dielectric constant film overlying a semiconductor substrate of a wafer;
annealing the wafer in an ambient having at a temperature of greater than approximately 470° C. and consisting essentially of an inert gas and an annealing gas selected from the group consisting of hydrogen and deuterium;
following the annealing, while maintaining the presence of the annealing gas in the ambient, reducing the ambient temperature to less than approximately 200° C.

11. The method of claim 10, wherein the anneal processing is performed after depositing a metal gate electrode on the dielectric film.

12. The method of claim 10, wherein depositing the high dielectric constant gate dielectric comprises depositing a material having a dielectric constant greater than 3.9.

13. The method of claim 11, wherein depositing the high dielectric constant gate dielectric comprises depositing a material consisting of a metal element and an element selected from the group consisting of oxygen, nitrogen, hafnium, zirconium, silicon, and aluminum.

14. The method of claim 11, wherein annealing the wafer further comprises placing the wafer in an inert ambient and ramping the temperature of the inert ambient to the temperature of greater than approximately 470° C. prior to introducing the annealing gas into the ambient.

15. The method of claim 14, wherein the inert ambient comprises a nitrogen ambient.

16. The method of claim 11, wherein a pressure of the annealing ambient is approximately 100 kPa.

17. The method of claim 11, wherein annealing the wafer comprises annealing the wafer for a duration in the range of approximately 10 to 50 minutes.

18. A semiconductor fabrication process, comprising:
depositing a gate dielectric having an equivalent oxide thickness (EOT) of less than approximately 2 nm; and
annealing the gate dielectric film by exposing the film to an ambient of an inert gas and a passivating gas at an annealing temperature; and
following the annealing, reducing depassivation of the gate dielectric film by reducing the temperature of the ambient while maintaining the presence of the passivating gas.

19. The method of claim 18, wherein depositing the gate dielectric comprises depositing a material comprising a metal element and oxygen.

20. The method of claim 19, wherein the passivating gas is selected from the group consisting of hydrogen gas and deuterium gas.

21. The method of claim 20, wherein the annealing temperature is in excess of approximately 470° C.

22. The method of claim 21, wherein reducing the temperature comprises reducing the temperature of the ambient to a temperature of less than approximately 100° C. while maintaining the presence of the passivating gas.
